(19) United States
(12) Patent Application Publication
(10) Pub. No.: US 2014/0210047 A1
(43) Pub. Date: Jul. 31, 2014

(54) SEMICONDUCTOR DEVICE

(71) Applicants: Kazunao Tajima, Niiza-shi (JP); Atsuhiko Tanaka, Niiza-shi (JP)

(72) Inventors: Kazunao Tajima, Niiza-shi (JP); Atsuhiko Tanaka, Niiza-shi (JP)

(73) Assignee: Sanken Electric Co., Ltd, Niiza-shi, Saitama (JP)

(21) Appl. No.: 14/240,453

(22) PCT Filed: May 25, 2012
(86) PCT No.: PCT/JP2012/063466

§ 371 Date: Feb. 24, 2014

(30) Foreign Application Priority Data
Aug. 25, 2011 (JP) 2011-183628

(51) Int. Cl. H01L 49/02

(52) U.S. Cl. CPC H01L 28/10
USPC 257/531

(57) ABSTRACT

A semiconductor device including: first and second semiconductor chips mounted on a base substrate; a third semiconductor chip, which is mounted on the base substrate, and outputs control signals controlling operations of the first and second semiconductor chips; a first transmission transformer, which is mounted on the base substrate, and has a reception-side terminal connected to the third semiconductor chip and a transmission-side terminal connected to the first semiconductor chip; and a second transmission transformer, which is mounted on the base substrate, and has a reception-side terminal connected to the third semiconductor chip and a transmission-side terminal connected to the second semiconductor chip, wherein the control signals are transmitted from the third semiconductor chip to the first semiconductor chip and the second semiconductor chip individually through the first transmission transformer and the second transmission transformer.

### TECHNICAL FIELD

The present invention relates to a semiconductor device onto which a plurality of semiconductor chips is mounted.

### BACKGROUND ART

For example, a high voltage-system semiconductor chip to be driven by a high power supply voltage and a low voltage-system semiconductor chip to be driven by a low power supply voltage are mounted on one base substrate, whereby reduction of parts count and space saving can be realized. At this time, it is considered effective to use an optical device and a transformer for signal transfer for the purpose of insulating separation between the semiconductor chips. For example, there is proposed a method of accelerating a transfer speed of a signal and extending a service life by using the transformer (for example, refer to Patent Literature 1).

### CITATION LIST

### [Patent Literature]

[PTL 1] Japanese Patent Laid-Open Publication No. 2010-34122

### SUMMARY OF INVENTION

### [Technical Problem]

However, no sufficient examination has been made for the technology using the transformer for the signal transfer. It is an object of the present invention to provide a semiconductor device, in which the transformer is used for the signal transfer, and the insulating separation between the semiconductor chips is enhanced.

### [Solution to Problem]

In accordance with an aspect of the present invention, there is provided a semiconductor device including: (A) a base substrate; (B) first and second semiconductor chips mounted on the base substrate; (C) a third semiconductor chip configured to output control signals controlling operations of the first and second semiconductor chips, the third semiconductor chip being mounted on the base substrate; (D) a first transmission transformer having a reception-side terminal connected to the third semiconductor chip and a transmission-side terminal connected to the first semiconductor chip, the first transmission transformer being mounted on the base substrate; and (E) a second transmission transformer having a reception-side terminal connected to the third semiconductor chip and a transmission-side terminal connected to the second semiconductor chip, the second transmission transformer being mounted on the base substrate, wherein the control signals are transmitted from the third semiconductor chip to the first semiconductor chip and the second semiconductor chip individually through the first transmission transformer and the second transmission transformer.

### [Advantageous Effects of Invention]

In accordance with the present invention, the semiconductor device can be provided, in which the transformer is used for the signal transfer, and the insulating separation between the semiconductor chips is enhanced.

### BRIEF DESCRIPTION OF DRAWINGS

FIG. 1 is a schematic plan view showing a structure example of a semiconductor device according to an embodiment of the present invention.

FIGS. 2(a) and 2(b) are schematic plan views showing structure examples of inductors which compose a transformer to be used in the semiconductor device according to the embodiment of the present invention.

FIG. 3 is a schematic cross-sectional view showing the structure example of the transformer to be used in the semiconductor device according to the embodiment of the present invention.

FIG. 4 is a schematic plan view showing another structure example of the semiconductor device according to the embodiment of the present invention.

### DESCRIPTION OF EMBODIMENTS

Next, a description is made of embodiments of the present invention with reference to the drawings. In the following description referring to the drawings, the same or similar reference numerals are assigned to the same or similar reference portions. However, it should be noted that the drawings are schematic and relationships between thickness and planar dimensions, length ratios of the respective portions, and the like are different from actual ones. Hence, specific dimensions should be determined in consideration of the following descriptions. Moreover, as a matter of course, portions in which mutual dimensional relationships and ratios are different from one another are also incorporated among the drawings.

Moreover, the embodiments to be described below illustrate devices and methods, which are for embodying the technical idea of this invention, and the technical idea of this invention does not specify shapes, structures, arrangements and the like of constituent components to those in the following description. The embodiments of this invention can be modified in various ways within the scope of claims.

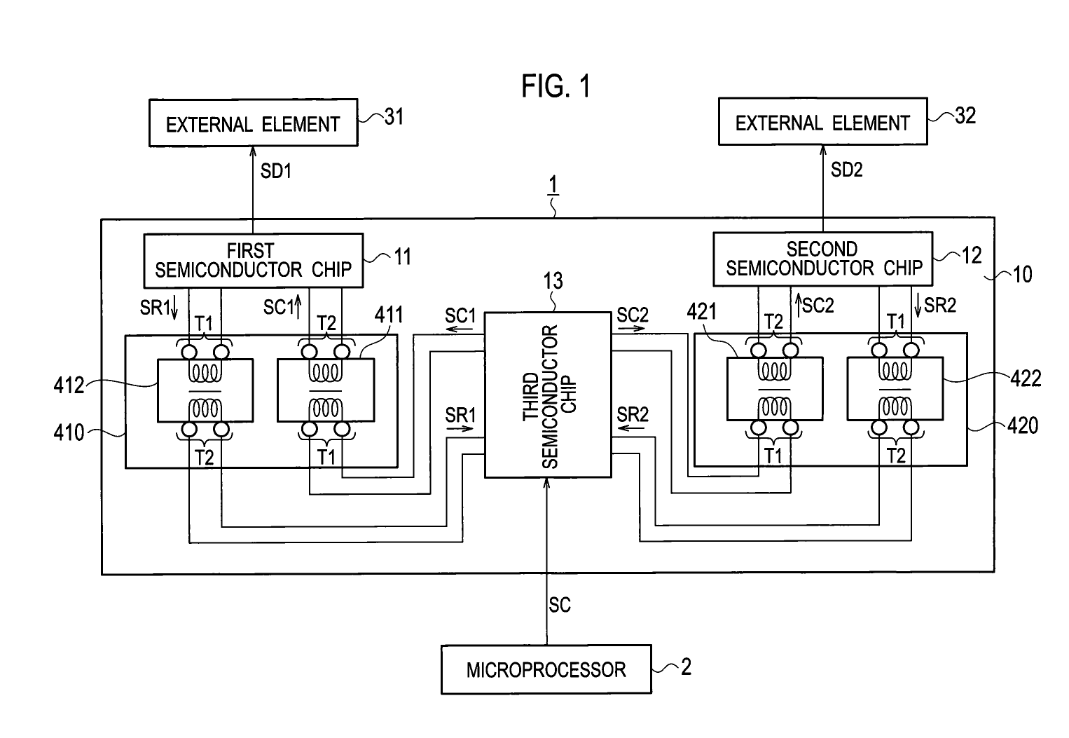

As shown in FIG. 1, a semiconductor device 1 according to an embodiment of the present invention includes a first semiconductor chip 11, a second semiconductor 12, a third semiconductor chip 13, a first transmission transformer 411 and a second transmission transformer 421, which are mounted on a base substrate 10. In the first transmission transformer 411, reception-side terminals T1 thereof are connected to the third semiconductor chip 13, and transmission-side terminals T2 thereof are connected to the first semiconductor chip 11. In the second transmission transformer 421, reception-side terminals T1 thereof are connected to the third semiconductor chip 13, and transmission-side terminal T2 thereof are connected to the second semiconductor chip 12. Here, in each of the transformers, the terminals, to which a signal propagating through the transformer is inputted from the outside, are referred to as “reception-side terminals”, and the terminals, to which the signal is outputted to the outside, are referred to as “transmission-side terminals” (the same applies to the following).

In the third semiconductor chip 13, there is formed a control circuit (not shown), which outputs control signals SC1 and SC2 individually controlling operations of the first semiconductor chip 11 and the second semiconductor chip 12. The control signal SC1 that controls the operations of the first semiconductor chip 11 is transmitted from the third semiconductor chip 13 through the first transmission transformer 411 to the first semiconductor chip 11. Moreover, the control signal SC2 that controls the operations of the second semiconductor chip 12 is transmitted from the third semiconductor chip 13 through the second transmission transformer 421 to the second semiconductor chip 12.

The semiconductor device 1 shown in FIG. 1 further includes: a first reception transformer 412 in which reception-side terminals T1 are connected to the first semiconductor chip 11, and transmission-side terminals T2 are connected to the third semiconductor chip 13; and a second reception transformer 422 in which reception-side terminals T1 are connected to the second semiconductor chip 12, and transmission-side terminals T2 are connected to the third semiconductor chip 13. Through the first reception transformer 412, a return signal SR1, which is sent from the first semiconductor chip 11 and corresponds to the control signal SC1, is transmitted to the third semiconductor chip 13. Moreover, through the second reception transformer 422, a return signal SR2, which is sent from the second semiconductor chip 12 and corresponds to the control signal SC2, is transmitted to the third semiconductor chip 13. Details of the return signal SR1 and the return signal SR2 will be described later in detail.

The first reception transformer 412 is arranged adjacent to the first transmission transformer 411, and the second reception transformer 422 is arranged adjacent to the second transmission transformer 421. In the example shown in FIG. 1, the first transmission transformer 411 and the first reception transformer 412 are formed on a first transformer board 410, and the second transmission transformer 421 and the second reception transformer 422 are formed on a second transformer board 420. However, the first transmission transformer 411 and the first reception transformer 412 may be individually formed on boards different from each other, and the second transmission transformer 421 and the second reception transformer 422 may be individually formed on boards different from each other. Note that, if efficiency of a manufacturing process and space saving are considered, then preferably, the first transmission transformer 411 and the first reception transformer 412 are formed on a single board, and the second transmission transformer 421 and the second reception transformer 422 are formed on a single board.

Although a structure example will be described later, printed boards, each having a structure in which a conductive thin film pattern and an insulator layer are stacked on each other, or the like are employable as the first transformer board 410 and the second transformer board 420. For example, the first transmission transformer 411, the first reception transformer 412, the second transmission transformer 421 and the second reception transformer 422 are pulse transformers through which pulse signals are propagable.

Hence, in the semiconductor device 1, a channel, in which the control signal SC1 propagates from the third semiconductor chip 13 to the first semiconductor chip 11, has an insulating structure using the first transmission transformer 411. Moreover, a channel, in which the return signal SR1 propagates from the first semiconductor chip 11 to the third semiconductor chip 13, has an insulating structure using the first reception transformer 412. In a similar way, a channel, in which the control signal SC2 propagates from the third semiconductor chip 13 to the second semiconductor chip 12, has an insulating structure using the second transmission transformer 421, and a channel, in which the return signal SR2 propagates from the second semiconductor chip 12 to the third semiconductor chip 13, has an insulating structure using the second reception transformer 422.

As shown in FIG. 1, the first transformer board 410, on which the first transmission transformer 411 and the first reception transformer 412 are formed, and the second transformer board 420, on which the second transmission transformer 421 and the second reception transformer 422 are formed, are arranged on the base substrate 10 so as to be opposed to each other while sandwiching the third semiconductor chip 13 therebetween.

Therefore, in the semiconductor device 1, electromagnetic noise generated in the first semiconductor chip 11 or the second semiconductor chip 12 is separated between the first semiconductor chip 11 and the second semiconductor chip 12. That is to say, the first semiconductor chip 11 and the second semiconductor chip 12 do not interfere with each other.

Note that, though the first transmission transformer 411 and the first reception transformer 412 are arranged adjacent to each other, and the second transmission transformer 421 and the second reception transformer 422 are arranged adjacent to each other, an influence by mutual noise is small.

In the first semiconductor chip 11 and the second semiconductor chip 12, for example, drive circuits (not shown), which drive external elements 31 and 32, are individually formed. Then, a drive signal SD1 that drives the external element 31 is outputted from the semiconductor device 1 to the external element 31, and a drive signal SD2 that drives the external element 32 is outputted to the external terminal 32. For example, the external elements 31 and 32 are insulated-gate bipolar transistors (IGBT) and the like. At this time, drive capabilities of the first semiconductor chip 11 and the second semiconductor chip may be equivalent to each other or may be different from each other. For the first semiconductor chip 11, the second semiconductor chip 12 and the third semiconductor chip 13, individual power supply circuits (not shown) which supply electric power to the respective semiconductor chips are prepared, and specifications of the respective power supply circuits are set in response to the drive capabilities to be individually required for the first semiconductor chip 11 and the second semiconductor chip 12.

For example, in order to realize an output current of approximately 10 A, the drive capability of the first semiconductor chip 11 is set high, and one IGBT with a large maximum rating is prepared as the external element 31 to be driven by the first semiconductor chip 11. In such a way, a high-speed ON/OFF operation of the external element 31 is possible.

The semiconductor device 1 can be used, for example, as a part of an on-vehicle electronic circuit system of a hybrid vehicle. Specifically, the first semiconductor chip 11 is used as a drive device that drives a high voltage-system circuit of the hybrid vehicle, and the second semiconductor chip 12 is used as a drive device that drives a low voltage-system circuit of the hybrid vehicle. Here, the low voltage-system circuit is a circuit to be supplied with a power supply by a 12V or 24V-system battery, the circuit belonging to the on-vehicle electronic circuit, a light such as a headlight and a turning indicator, an ignition device of an internal combustion engine such as a gasoline engine and a diesel engine, or the like. The high voltage-system circuit is a circuit that drives an electric motor, or the like. In order to drive the electric motor, for example, an output of a 200V-system battery is raised to a voltage as high as 500V to 900V.

Note that the control signals SC1 and SC2, which control the operations of the first semiconductor chip 11 and the second semiconductor chip 12, are distributed by the third semiconductor chip 13 to either the first semiconductor chip 11 or the second semiconductor chip 12, for example, in response to contents of a control signal SC to be transmitted from a microprocessor 2. Moreover, as mentioned above, the third semiconductor chip 13 receives the return signal SR1, which is sent from the first semiconductor chip 11, through the first reception transformer 412, and receives the return signal SR2, which is sent from the second semiconductor chip 12, through the second reception transformer 422.

The return signal SR1 is generated so that a value thereof can be fixed in response to the operations of the first semiconductor chip 11 that has received the control signal SC1. The third semiconductor chip 13 determines whether or not the first semiconductor chip 11 operates normally with reference to the control signal SC1 and the return signal SR1. For example, a configuration is adopted in advance so that the return signal SR1 can be generated as an inverted signal of the control signal SC1 if the first semiconductor chip 11 operates normally, and the third semiconductor chip 13 generates an exclusive-NOR (XNOR) signal of the control signal SC1 and the return signal SR1. Then, it is determined that the first semiconductor chip 11 operates normally if the XNOR signal is “0”, and it is determined that the first semiconductor chip 11 does not operate normally if the XNOR signal is “1”.

In a similar way, the third semiconductor chip 13 determines whether or not the second semiconductor chip 12 operates normally with reference to the control signal SC2 and the return signal SR2.

In the case of having determined that at least either one of the first semiconductor chip 11 or the second semiconductor chip 12 does not operate normally, the third semiconductor chip 13 stops the operations of the semiconductor device 1 for example.

As described above, the control signals SC1 and the SC2 and the return signals SR1 and SR2 are compared with each other, whereby fail-safe design for handling the case of abnormality can be achieved by mounting a low voltage lockout circuit, an abnormal load detection circuit, a soft shutdown circuit or the like on the semiconductor device 1.

Next, a description is made of the structure example of the first transmission transformer 411, the first reception transformer 412, the second transmission transformer 421 and the second reception transformer 422.

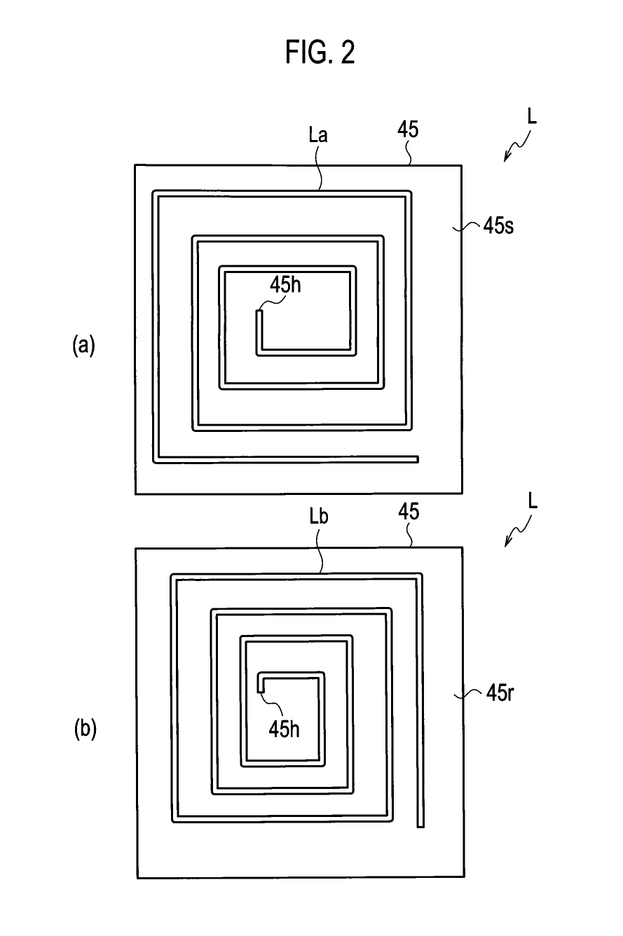

For each of the above-described transformers, there is employable a structure, for example, as shown in FIGS. 2(a) and 2(b), the structure using planar inductors, each of which is composed by arranging a spiral conductive thin film pattern on a plane. In an example shown in FIGS. 2(a) and 2(b), planar inductors La and Lb are formed on a front surface 45s and back surface 45r of a planar core material 45, respectively, and an end portion of the planar inductor La and an end portion of the planar inductor Lb are connected to each other by a through hole portion 45h that penetrates the core material 45, whereby one inductor L is formed. For a material of the conductive thin film patterns of the planar inductors La and Lb, for example, copper foil and the like can be used. Moreover, for the core material 45, an epoxy material or the like is employable. For the purpose of miniaturization of the semiconductor device 1, preferably, a size of the inductor L is small, and for example, a line and space (L/S) of the planar inductors La and Lb is 50 μm/50 μm.

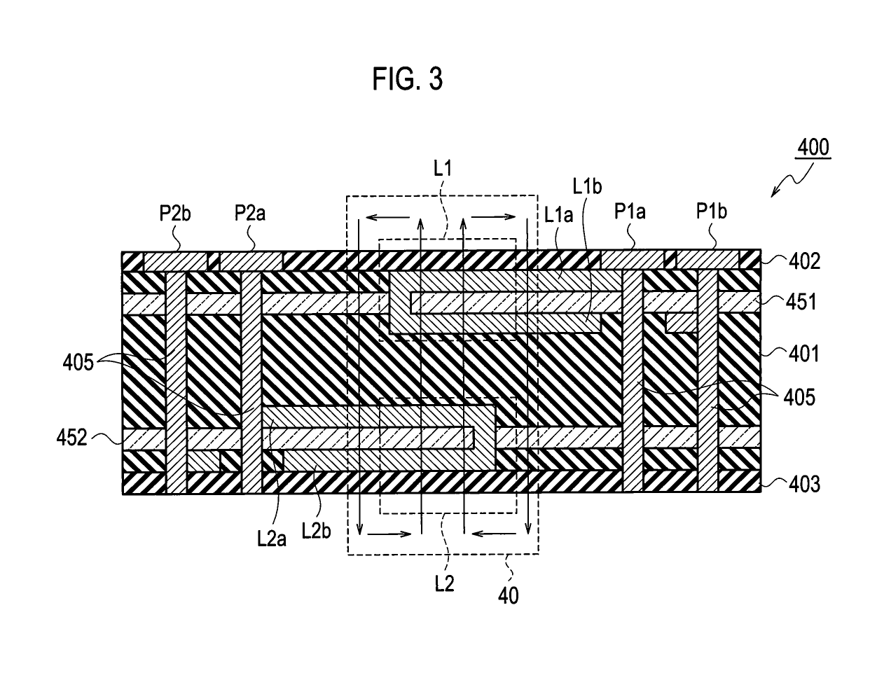

Two inductors L are stacked on each other while sandwiching the insulator layer therebetween, whereby there is formed a board transformer employable as the first transmission transformer 411, the first reception transformer 412, the second transmission transformer 421 and the second reception transformer 422. For example, as shown in FIG. 3, a board transformer 40 is formed in a region where an inductor L1 and an inductor L2 overlap each other while interposing an insulator layer 401 therebetween when viewed from the above. Arrows shown in FIG. 3 denote a concept of a magnetic field of the board transformer 40.

In the example shown in FIG. 3, the inductor L1, which is composed of planar inductors L1a and L1b arranged on a front surface and back surface of a core material 451, respectively, and the inductor L2, which is composed of planar inductors L2a and L2b individually arranged on both surfaces of a core material 452, are stacked on each other while sandwiching the insulator layer 401 therebetween, whereby a transformer board 400 is configured. For the purpose of enhancing a degree of coupling, preferably, centers of the inductor L1 and the inductor L2 are prevented from overlapping each other.

For the insulator layer 401, for example, a prepreg of an epoxy material or the like is employable. Note that, on and under a stacked body composed of, for example, the inductor L1, the insulator layer 401 and the inductor L2, solder resists 402 and 403 are arranged, whereby the transformer board 400 is formed. A thickness of the transformer board 400 is set, for example, so as to match with heights of the first semiconductor chip 11, the second semiconductor chip 12 and the third semiconductor chip 13. For example, a thickness of the transformer board 400 is set at approximately 400 μm. Moreover, a film thickness of the insulator layer 401 between the inductor L1 and the inductor L2 is set, for example, at approximately 100 μm.

One end portion of the planar inductor L1a and one end portion of the planar inductor L1b are connected to each other. Another end portion of the planar inductor L1a is connected to a pad P1a arranged on a front surface of the transformer board 400, and another end portion of the planar inductor L1b is connected to a pad P1b arranged on the front surface of the transformer board 400. In a similar way, one end portion of the planar inductor L2a and one end portion of the planar inductor L2b are connected to each other. Another end portion of the planar inductor L2a is connected to a pad P2a arranged on the front surface of the transformer board 400, and another end portion of the planar inductor L2b is connected to a pad P2b arranged on the front surface of the transformer board 400.

For example, as shown in FIG. 3, the planar inductors L1a, L1b, L2a and L2b and the pads P1a, P1b, P2a and P2b are electrically connected to each other by plugs 405 in which a conductive material is embedded through holes which penetrate the transformer board 400.

For example, the pads P1a and P1b of the transformer board 400 are used as reception-side terminals of the board transformer 40, and the pads P2a and P2b of the transformer board 400 are used as transmission-side terminals of the board transformer 40. At this time, in the case where the structure shown in FIG. 3 is employed for the first transmission transformer 411, output terminals of the third semiconductor 13 are connected to the pads P1a and P1b, and input terminals of the first semiconductor chip 11 are connected to the pads P2a and P2b. In such a way, the control signal SC1 as a pulse signal is transmitted from the third semiconductor chip 13 to the first semiconductor chip 11. Moreover, the return signal SR1 as a pulse signal is transmitted from the first semiconductor chip 11 to the third semiconductor chip 13 in such a manner that the output terminals of the first semiconductor chip 11 are connected to the pads P1a and P1b, and that the input terminals of the third semiconductor chip 13 are connected to the pads P2a and P2b.

In a similar way, the control signal SC2 is transmitted from the third semiconductor chip 13 to the second semiconductor chip 12 in such a manner that output terminals of the third semiconductor chip 13 are connected to the pads P1a and P1b, and that input terminals of the second semiconductor chip 12 are connected to the pads P2a and P2b. The return signal SR2 is transmitted from the second semiconductor chip 12 to the third semiconductor chip 13 in such a manner that output terminals of the second semiconductor chip 12 are connected to the pads P1a and P1b, and that input terminals of the third semiconductor chip 13 are connected to the pads P2a and P2b.

Note that, as already mentioned, preferably, the board transformer 40 to be used as the first transmission transformer 411 and the board transformer 40 to be used as the first reception transformer 412 are formed in the first transformer board 410. Moreover, the board transformer 40 to be used as the second transmission transformer 421 and the board transformer 40 to be used as the second reception transformer 422 are formed in the second transformer board 420.

The semiconductor device 1 shown in FIG. 1 is formed as a package, for example, by mold sealing and the like. Note that, for example, a copper alloy frame and the like are employable for the base substrate 10.

As described above, in accordance with the semiconductor device 1, according to the embodiment of the present invention, the transformers are used for the route through which the signal propagates, whereby the electromagnetic noise between the semiconductor chips is separated. Moreover, the first to third semiconductor chips 11, 12 and 13 and the first and second transformer boards 410 and 420 are mounted on the base substrate 10, and accordingly, miniaturization of a package is possible. As a result, the semiconductor device 1 can be provided, in which the insulating separation between the semiconductor chips is enhanced, and miniaturization, price reduction and processing acceleration are achieved. For example, a semiconductor device can be realized, in which an output is large and interference between the semiconductor chips by the electromagnetic noise is suppressed.

Unlike the embodiment of the present invention, in the case of using an optical device for a signal propagation route, brightness of a light emitting element such as a light emitting diode is deteriorated, whereby light reception characteristics of a light receiving element is lowered, and a signal transfer response is lowered. Furthermore, when the optical device is placed under a high-temperature environment, the deterioration of the brightness of the light emitting element and the lowering of the light reception characteristics of the light receiving element are accelerated, and a service life is shortened.

As opposed to this, in the semiconductor device 1 according to the embodiment of the present invention, not the optical device but the transformer is used for the signal propagation route, and accordingly, the transfer response of the signal is not lowered, or the service life is not shortened. For example, the semiconductor device 1 according to the embodiment is suitable also for on-vehicle use where an ambient temperature becomes a high temperature.

Note that, in the case of employing the copper alloy frame and the like for the base substrate 10, a die pad, which is a semiconductor chip mounting portion of the copper alloy frame, is divided into three portions, and the first to third semiconductor chips 11, 12 and 13 are mounted on individually separate die pads. In such a way, the first to third semiconductor chips 11, 12 and 13 are insulatingly separated from one another electrically and magnetically. An interval between the die pad on which the first semiconductor chip 11 is mounted and the die pad on which the third semiconductor chip 13 is mounted is widened, and in a space thus widened, the first transformer board 410 is arranged so as to be bridged over the same, whereby a thickness of the copper alloy frame can be suppressed. In a similar way, an interval between the die pad on which the second semiconductor chip 12 is mounted and the die pad on which the third semiconductor chip 13 is mounted is widened, and in a space thus widened, the second transformer board 420 is arranged so as to be bridged over the same, whereby the thickness of the copper alloy frame can be suppressed. As a result, the miniaturization of the semiconductor device 1 is possible also in a thickness direction of the package.

### Other Embodiments

As above, the present invention has been described based on the embodiment; however, it should not be understood that the description and the drawings, which form a part of this disclosure, limit the present invention. From this disclosure, varieties of alternative embodiments, examples and operation technologies will be obvious for those skilled in the art.

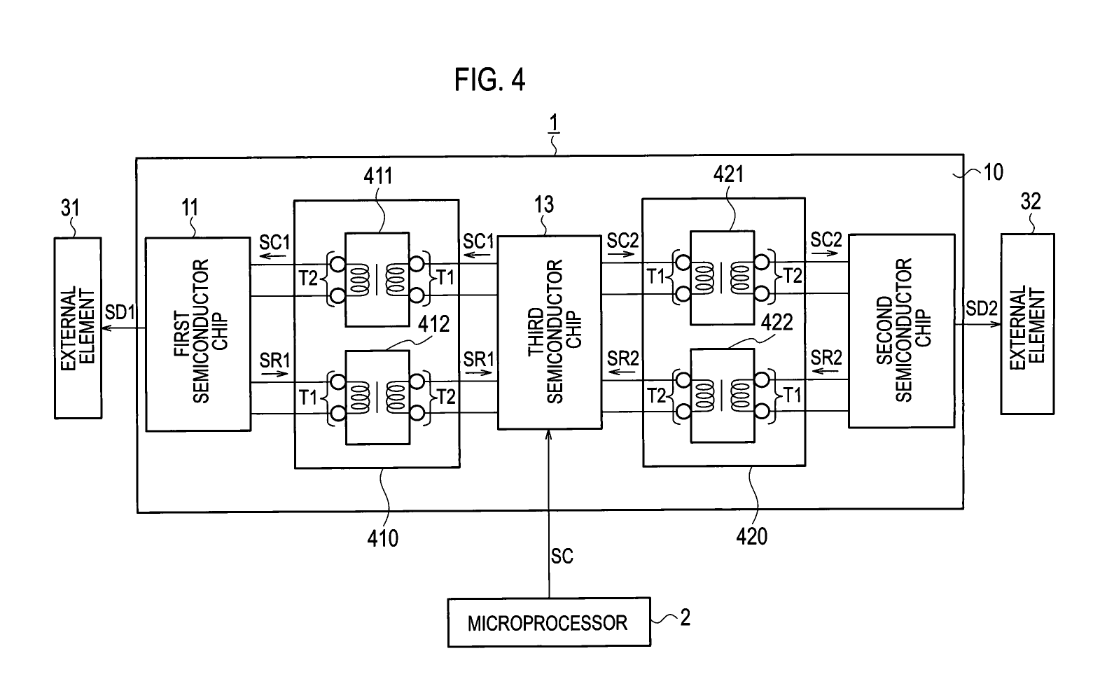

For example, in the above-described embodiment, the example is shown, where the first semiconductor chip 11, the second semiconductor chip 12 or the like is arranged so that an end surface thereof, to which the control signal SC of the semiconductor device 1 is inputted, and an end surface of the semiconductor device 1, from which the drive signal SD1 or SD2 is outputted, can be opposed to each other; however, as shown in FIG. 4, the drive signals SD1 and SD2 may be outputted from right and left end surfaces of the first semiconductor chip 11, the second semiconductor chip 12 and the like when viewed from end surfaces to which the control signals SC are inputted.

As described above, it is a matter of course that the present invention incorporates a variety of embodiments and the like, which are not described herein. Hence, the technical scope of the present invention is determined only by the invention specifying items according to the scope of claims reasonable from the above description.

### INDUSTRIAL APPLICABILITY

The semiconductor device of the present invention is applicable for the usage purpose of the semiconductor device with the configuration in which the plurality of semiconductor chips is separated by the transformers.

1. A semiconductor device comprising:
a base substrate;
first and second semiconductor chips mounted on the base substrate;
a third semiconductor chip configured to output control signals controlling operations of the first and second semiconductor chips, the third semiconductor chip being mounted on the base substrate;
a first transmission transformer having a reception-side terminal connected to the third semiconductor chip and a transmission-side terminal connected to the first semiconductor chip, the first transmission transformer being mounted on the base substrate; and
a second transmission transformer having a reception-side terminal connected to the third semiconductor chip and a transmission-side terminal connected to the second semiconductor chip, the second transmission transformer being mounted on the base substrate,
wherein the control signals are transmitted from the third semiconductor chip to the first semiconductor chip and the second semiconductor chip individually through the first transmission transformer and the second transmission transformer.

2. The semiconductor device according to claim 1, further comprising:
a first reception transformer having a reception-side terminal connected to the first semiconductor chip and a transmission-side terminal connected to the third semiconductor chip, the first reception transformer being arranged adjacent to the first transmission transformer,
wherein a return signal corresponding to the control signal is transmitted from the first semiconductor chip to the third semiconductor chip through the first reception transformer.

3. The semiconductor device according to claim 2, wherein the first transmission transformer and the first reception transformer are formed on a single board mounted on the base substrate.

4. The semiconductor device according to claim 1, further comprising:
a second reception transformer having a reception-side terminal connected to the second semiconductor chip and a transmission-side terminal connected to the third semiconductor chip, the second reception transformer being arranged adjacent to the second transmission transformer,
wherein a return signal corresponding to the control signal is transmitted from the second semiconductor chip to the third semiconductor chip through the second reception transformer.

5. The semiconductor device according to claim 4, wherein the second transmission transformer and the second reception transformer are formed on a single board mounted on the base substrate.

6. The semiconductor device according to claim 1, wherein the third semiconductor chip is arranged between the first transmission transformer and the second transmission transformer.

7. The semiconductor device according to claim 1, wherein the first and second transmission transformers are board transformers, each including:
first and second inductors individually arranged on two opposite principal surfaces of a core material, each of the first and second inductors being composed of two conductive thin film patterns having mutual end portions connected to each other by a through-hole portion penetrating the core material; and
an insulator layer arranged between the first and second inductors.
